(19) United States
(12) Patent Application Publication
(10) Pub. No.: US 2007/0008777 A1
(43) Pub. Date: Jan. 11, 2007

(54) NON-VOLATILE MEMORY CELL AND OPERATING METHOD THEREOF

(76) Inventors: Ming-Hsiang Hsueh, Hsinchu (TW); Ming-Chang Kuo, Hsinchu (TW); Min-Ta Wu, Hsinchu (TW); Chao-Lun Yu, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,777

(22) Filed: May 3, 2006

Related U.S. Application Data
(62) Division of application No. 11/160,742, filed on Jul. 7, 2005, now abandoned.

(51) Int. Cl. G11C 11/34

(52) U.S. Cl. 365/185.18; 365/185.29

(57) ABSTRACT

A non-volatile memory is described. The non-volatile memory includes a first source/drain region, a second source/drain region, a charge-trapping layer and a gate layer. The first source/drain region is disposed beside the top sidewall of a trench in a substrate. The second source/drain region is disposed in the substrate at the bottom of the trench. The gate layer is disposed in the trench and on the substrate. The charge-trapping layer is disposed between the gate layer and the substrate. A plurality of assisted charges is stored in one of the sides of the charge-trapping layer.

### CROSS-REFERENCE TO RELATED APPLICATION

This application is a divisional of a prior application Ser. No. 11/160,742, filed on Jul. 7, 2005. All disclosures are incorporated herewith by reference.

### BACKGROUND OF THE INVENTION

1. Field of the Invention

The present invention relates to a memory and operating method thereof. More particularly, the present invention relates to a non-volatile memory cell and operating method thereof.

2. Description of the Related Art

Among the various types of memory products, non-volatile memory is a memory device that has been widely used inside personal computer systems and electron equipment because data can be stored, read out or erased from the non-volatile memory many times. Moreover, the stored data are retained even after power supplying the devices is cut off.

In recent years, a memory device with a vertical structure has been developed. Because the channel of this type of memory device extends in a direction perpendicular to the substrate, the dimension of each memory device is significantly reduced. Furthermore, the memory has a wider channel width so that the so-called second-bit effect is also minimized.

However, the vertical layout of a memory device is not without problems. A vertical layout prevents the pocket implantation of the source/drain regions and hence the hot carrier effect will be inferior. When the memory device is programmed by the channel hot electron injection (CHEI) method, a larger current needs to flow so that more energy is wasted in the process.

### SUMMARY OF THE INVENTION

Accordingly, at least one objective of the present invention is to provide a non-volatile memory cell and operating method thereof that can use a smaller current in programming operation to boost programming efficiency.

To achieve these and other advantages and in accordance with the purpose of the invention, as embodied and broadly described herein, the invention provides a non-volatile memory cell. The non-volatile memory includes a first source/drain region, a second source/drain region, a charge-trapping layer and a gate layer. The first source/drain region is disposed beside the top sidewall of a trench in a substrate. The second source/drain region is disposed in the substrate at the bottom of the trench. The gate layer is disposed in the trench and on the substrate. The charge-trapping layer is disposed between the gate layer and the substrate. A plurality of assisted charges is stored in one of the sides of the charge-trapping layer.

According to the embodiment of the present invention, the charge-trapping layer is a composite dielectric layer, for example. The composite dielectric layer is an oxide-nitride-oxide layer, for example.

According to the embodiment of the present invention, the gate layer is a doped polysilicon layer, for example.

The present invention also provides a method suitable for operating a non-volatile memory cell. The non-volatile memory cell comprises a first source/drain region, a second source/drain region, a charge-trapping layer and a gate layer. The first source/drain region is disposed beside the top sidewall of a trench in a substrate. The second source/drain region is disposed in the substrate at the bottom of the trench. The gate layer is disposed in the trench and on the substrate. The charge-trapping layer is disposed between the gate layer and the substrate. A plurality of assisted charges is stored in one of the sides of the charge-trapping layer. The operating method includes driving electrons into the other side of the charge-trapping layer to program the non-volatile memory cell and driving holes into the other side of the charge-trapping layer to erase the data within the non-volatile memory cell. To read data from the non-volatile memory cell, a first voltage is applied to the gate and a second voltage is applied to the source/drain region close to the assisted charges.

According to the embodiment of the present invention, the assisted charges is stored on that side of the charge-trapping layer close to the second source/drain region, the first voltage is a positive voltage and the second voltage is a positive voltage. A third voltage can be applied to the gate layer and a fourth voltage can be applied to the first source/drain region so that electrons are driven into the other side of the charge-trapping layer to program the non-volatile memory cell. The third voltage is a positive voltage and the fourth voltage is a positive voltage. A fifth voltage can be applied to the gate layer and a sixth voltage can be applied to the first source/drain region so that holes are driven into the other side of the charge-trapping layer to erase data from the non-volatile memory cell. The fifth voltage is a negative voltage and the sixth voltage is a positive voltage.

In the present invention, a plurality of assisted charges is trapped on one side of the charge-trapping layer. When the electron driving method is used to perform a programming operation, the sharp electric field created between the source/drain regions and the high threshold voltage created by the assisted charges can increase the programming efficiency and lower the programming current.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a non-volatile memory cell according to one embodiment of the present invention.

FIG. 2 is a schematic cross-sectional view showing the operating mode for programming data into a non-volatile memory cell according to one embodiment of the present invention.

FIG. 3 is a schematic cross-sectional view showing the operating mode for erasing data from a non-volatile memory cell according to one embodiment of the present invention.

FIG. 4 is a schematic cross-sectional view showing the operating mode for reading data from a non-volatile memory cell according to one embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

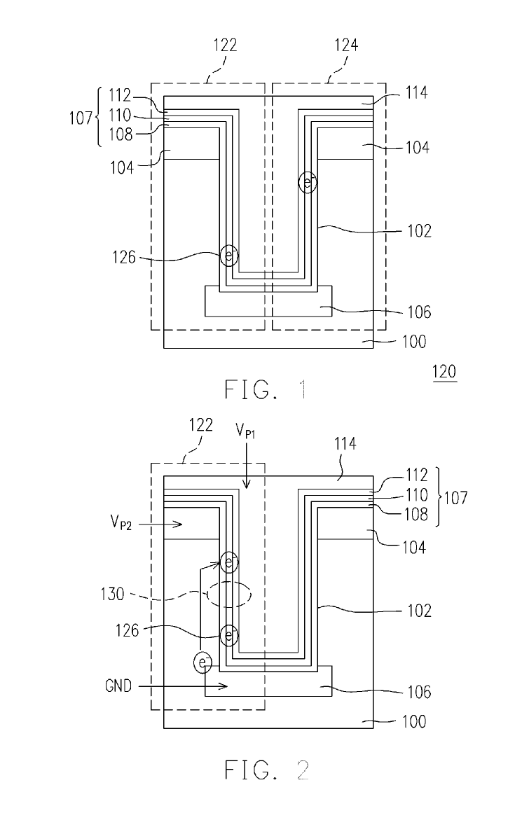

FIG. 1 is a schematic cross-sectional view of a non-volatile memory cell according to one embodiment of the present invention. As shown in FIG. 1, the non-volatile memory unit 120 includes two memory cells 122 and 124. Each memory cell (122 or 124) comprises a first source/drain region 104, a second source/drain region 106, a charge-trapping layer 107 and a gate layer 114. The first source/drain region 104 is disposed inside a substrate 100 and located beside the top sidewall of a trench 102. The second source/drain region 106 is disposed in the substrate 100 at the bottom of the trench 102. The gate layer is disposed in the trench 102 and on the substrate 100 and fabricated using doped polysilicon, for example. The charge-trapping layer 107 is disposed between the gate layer 114 and the substrate 100. The charge-trapping layer 107 is a composite dielectric layer comprising a bottom dielectric layer 108, a middle dielectric layer 110 and a top dielectric layer 112. The bottom dielectric, middle dielectric, and top dielectric layer can be silicon oxide, silicon nitride, and silicon oxide, respectively, for example.

In the present invention, one of the sides of the charge-trapping layer 107 in the memory cell 122 or 124 has a plurality of assisted charges 126 therein. The assisted charges 126 can be trapped, for example, in the charge-trapping layer 107 close to the source/drain region 104 (the memory cell 124 in FIG. 1). However, the assisted charges 126 can be trapped, for example, in the charge-trapping layer 107 close to the second source/drain region 106 (the memory cell 122 in FIG. 1).

Since the non-volatile memory cell in the present invention is a memory cell with a vertical layout, it occupies an area smaller than a conventional horizontal memory cell. As a result, the non-volatile memory design in the present invention can preserve wafer area and increase the level of device integration. In the following, various methods of operating the non-volatile memory according to the present invention are described.

FIG. 2 is a schematic cross-sectional view showing the operating mode for programming data into a non-volatile memory cell according to one embodiment of the present invention. The present invention chooses the channel electron driving method to program a memory device. As shown in FIG. 2, the assisted charges 126 of the memory cell 122 is stored inside the charge-trapping layer 107 on that side close to the source/drain region 106. To carry out a programming operation, a voltage Vₚ₁ is applied to the gate layer 114, another voltage Vₚ₂ is applied to the source/drain region 104 and the source/drain region 106 is connected to a ground. Both the voltage Vₚ₁ and the voltage Vₚ₂ are positive voltages. Through the aforementioned voltages, a current flowing from the source/drain region 106 toward the source/drain region 104 is produced. A portion of the electrons in the current will penetrate through the bottom dielectric layer 108 into that side of the charge-trapping layer 107 close to the source/drain region 104 and program the memory cell 122.

It should be noted that a fixed high threshold voltage is set by the plurality of assisted charges 126 trapped on one side of the charge-trapping layer 107. Hence, during the memory cell programming operation, an abrupt electric field 130 is set up between the source drain regions 104 and 106 and the size of current that flows into the source/drain region 104 is curtailed. As a result, the electrons driving into the charge-trapping layer 107 is increased and the programming efficiency is improved. Accordingly, compared with a conventional memory device without any stored assisted charges 126 therein, the present invention can use a small programming current to program data into the memory device and yet attain a higher level of programming efficiency.

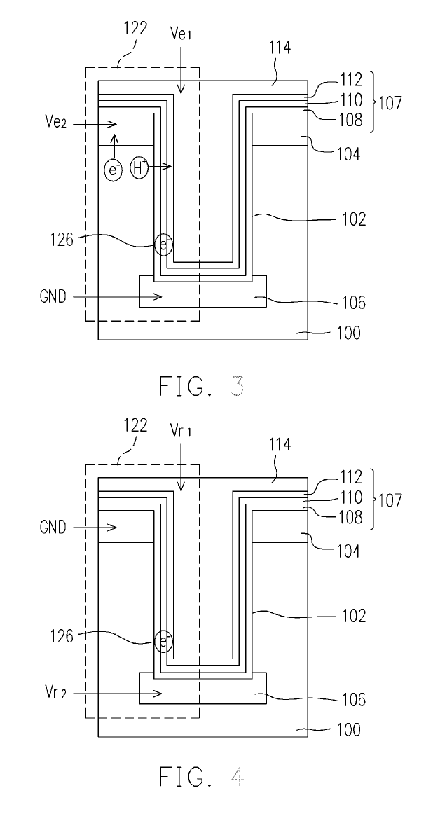

FIG. 3 is a schematic cross-sectional view showing the operating mode for erasing data from a non-volatile memory cell according to one embodiment of the present invention. In the embodiment of the present invention, the band-to-band induced hot hole injection method is used to erase data from the memory cells. As shown in FIG. 3, the assisted charges of the memory cell 122 are trapped on that side of the charge-trapping layer 107 close to the source/drain region 106. To performing the erasing operation, a voltage Vₑ₁ is applied to the gate layer 114, a voltage Vₑ₂ is applied to the source/drain region 104 and the source/drain region 106 is connected to a ground. The voltage Vₑ₁ is a negative voltage and the voltage Vₑ₂ is a positive voltage. Through the application of various voltages, electron/hole pairs will be produced in the channel close tot he source/drain region 104. Holes, attracted by the voltage Vₑ₁, are drived into that side of the charge-trapping layer 107 close to the source/drain region 104 for erasing the data within the memory cell 122. Meanwhile, the electrons flow to the source/drain region 104.

FIG. 4 is a schematic cross-sectional view showing the operating mode for reading data from a non-volatile memory cell according to one embodiment of the present invention. As shown in FIG. 4, the assisted charges of the memory cell 122 is trapped on that side of the charge-trapping layer 107 close to the source/drain region 106. To read data from the memory cell 122, a voltage Vᵣ₁ is applied to the gate layer 114, the source/drain region is connected to a ground and a voltage Vᵣ₂ is applied to the source/drain region 106. Both the voltage Vᵣ₁ and the voltage Vᵣ₂ are positive voltages.

In the aforementioned method of operating the memory device, the memory cell 122 and the trapped assisted charges close to the source/drain region 106 are used in the illustration. However, the assisted charges 126 may reside on that side of the charge-trapping layer 107 close to the source/drain region 104. Hence, the memory device can be operated through manipulating the voltages applied to the gate layer 114 and the source/drain regions 104 and 106 respectively.

In summary, major advantages of the present invention at least include:

1. With a vertical memory cell design, wafer area occupation per unit cell can be reduced and the level of integration can be increased.

2. Because one of the sides of the charge-trapping layer within the memory cell contains assisted charges, the programming efficiency of the electron driving method is boosted through the abrupt electric field between the source/drain regions and the high threshold voltage provided by the assisted charges. Thus, a smaller programming current can be used and a higher programming efficiency can be attained.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of operating a non-volatile memory cell comprising a first source/drain disposed beside a sidewall at the top of a trench in a substrate, a second source/drain region disposed in the substrate at the bottom of the trench, a gate layer disposed in the trench and on the substrate, a charge-trapping layer disposed between the gate layer and the substrate, and a plurality of assisted charges disposed in one of the sides of the charge-trapping layer, the operating method comprising:
performing a programming operation by driving electrons into the other side of the charge-trapping layer to program data into the non-volatile memory cell;
performing an erasing operation by driving holes into the other side of the charge-trapping layer to erase data from the non-volatile memory cell; and
performing a reading operation by applying a first voltage to the gate layer and applying a second voltage to the source/drain region close to the assisted charges to read data from the non-volatile memory.

2. The operating method of claim 1, wherein the assisted charges are trapped on that side of the charge-trapping layer closer to the second source/drain region.

3. The operating method of claim 2, wherein the first voltage is a positive voltage and the second voltage is a positive voltage.

4. The operating method of claim 2, wherein the step of performing a programming operation further includes applying a third voltage to the gate layer and applying a fourth voltage to the first source/drain region so that electrons are driven into the other side of the charge-trapping layer to program the non-volatile memory cell.

5. The operating method of claim 4, wherein the third voltage is a positive voltage and the fourth voltage is a positive voltage.

6. The operating method of claim 2, wherein the step of performing an erasing operation includes applying a fifth voltage to the gate layer and applying a sixth voltage to the first source/drain region so that holes are driven into the other side of the charge-trapping layer to erase data from the non-volatile memory cell.

7. The operating method of claim 6, wherein the fifth voltage is a negative voltage and the sixth voltage is a positive voltage.
